(19) United States
(12) Patent Application Publication
(10) Pub. No.: US 2003/0207549 A1
(43) Pub. Date: Nov. 6, 2003

(54) Method of forming a silicate dielectric layer

(76) Inventor: Jason Jyh-Shyang Jenq, Ping-Tung City (TW)

Correspondence Address: POWELL, GOLDSTEIN, FRAZER & MURPHY LLP, P.O. BOX 97223, WASHINGTON, DC, 20090-7223, US

(21) Appl. No.: 10/136,349

(22) Filed: May 2, 2002

(51) Int. Cl. H01L 21/28

(52) U.S. Cl. 438/582

(57) ABSTRACT

This invention relates to a method for forming a dielectric layer, more particularly, to a method for forming a silicate dielectric layer. The first step of the present invention is to form a silicate layer on the substrate of the wafer by using a physical vapor deposition (PVD) procedure. The silicate layer is a hafnium silicate (HfSi) layer or a zirconium silicate (ZrSi) layer. Then the silicate layer is treated to become a gate dielectric layer or an inter-layer dielectric layer which has higher a dielectric constant by using a rapid thermal annealing (RTA) procedure in a environment which is filled of nitrogen or ammonia.

### BACKGROUND OF THE INVENTION

1. Field of the Invention

This invention relates to a method for forming a dielectric layer, more particularly, to a method for forming a silicate dielectric layer to form a gate dielectric or a inter-layer dielectric layer which has a higher dielectric constant

2. Description of the Prior Art

Gate dielectric layer is very important in the metal oxide semiconductor field effect transistor (MOSFET). In order to increase the velocity of the elements and decrease the critical voltage, the thickness of the gate dielectric layer will become thinner and thinner. If the thickness of the gate dielectric layer is thinner and thinner, the requests of the gate dielectric layer is stricter and stricter. Successful gate dielectric layer must have lower leakage current (or higher breakdown electric field).

When the thickness of the gate dielectric layer becomes thicker, the electric field intensity of the gate dielectric layer will be increased in a fixed operating voltage. In this condition, the current will affect the leakage and the breakdown defects by tunneling ways. There are several methods in checking the qualities of the gate dielectric layer, such as: (1) time-zero dielectric breakdown (TZDB): adding the first level voltage into a test piece until the leakage current being higher than a value or producing a jump current; (2) charge breakdown: adding a fixed current into a test piece until there being a jump current in the voltage; (3) gate voltage shift: adding a fixed current into a test piece and measuring the variation of the voltage of the gate; (4) life time: adding several voltages into the test piece, measuring leakage time, and forecasting the life time.

The more traditional method for forming the gate dielectric layer is to use the thermal oxide procedure to form an oxide layer on the substrate to be the gate dielectric layer. Following the width of the procedure is narrower and narrower, the thickness of the gate dielectric layer is thinner and thinner to conform the structure of the semiconductor elements whose volume are smaller. Therefore, the newer method in the present is to use a hafnium dioxide layer to be the gate dielectric layer. This method can get the higher dielectric constant from the thinner gate dielectric layer to conform the needs of the reduced semiconductor elements.

Referring to FIG. 1, this shows a diagram in forming a hafnium dioxide layer on a substrate of a wafer. At first, a wafer, which comprises a substrate 10, is provided. This substrate can be a silicon substrate. Then a hafnium dioxide layer 20 is formed on the substrate 10. The hafnium dioxide layer 20 is usually formed by using the physical vapor deposition procedure.

Referring to FIG. 2, his shows a diagram in forming a conductive layer on the hafnium dioxide layer. The conductive layer 30, which is used to be an electrode or a gate, is formed on the hafnium dioxide layer 20 by using a direct current sputtering procedure. A material of the conductive layer 30 is tantalum nitride (TaN), titanium nitride (TiN), or a silicon layer, wherein the silicon layer is polysilicon layer. When the material of the conductive layer 30 is tantalum nitride or titanium nitride, the conductive layer 30 is used to be the electrode and the hafnium dioxide layer 20 is used to be the inter-layer dielectric layer. When the material of the conductive layer 30 is the silicon layer, the conductive layer 30 is used to be the gate and the hafnium dioxide layer 20 is used to be the gate dielectric layer. Then the partial hafnium dioxide layer 20 and the partial conductive layer 30 are removed to show the partial substrate 10 by using a photolithography and a etching procedure. Then ions, which are needed in the procedure, are implanted into the substrate and an annealing procedure is proceeded to form a source/drain region in the substrate.

Referring to FIG. 3, this shows a diagram in forming a silicon dioxide layer on an interface between the substrate and the hafnium dioxide layer. When the wafer is placed into a reaction chamber to proceed the annealing procedure to form the source/drain region, the silicon dioxide layer 40 will be formed on the interface between the substrate 10 and the hafnium dioxide layer 20. The hafnium dioxide layer 20 is a porosity material. Therefore, the hafnium dioxide layer 20 will generate a oxygen diffusion path more easily when it is in a higher temperature environment to formed the silicon dioxide layer 40 on the interface between the substrate 10 and the hafnium dioxide layer 20. The silicon dioxide layer 40 will decrease a dielectric constant of an interface between the substrate 10 and the hafnium dioxide layer 20.

The silicon dioxide layer 40 will also decrease a stability of a threshold voltage (Vₜₕ).

Although the hafnium dioxide layer, which is used to be the gate dielectric layer or an inter-layer dielectric layer, can be got the higher dielectric constant in the thinner condition to conform the needs of the gate dielectric layer. The silicon dioxide layer is formed on the interface between the substrate and the hafnium dioxide layer due to the porosity advantage of the hafnium dioxide layer in the following thermal annealing procedure. The silicon dioxide layer will decrease the dielectric constant of a dielectric layer and will affect the stability of the threshold voltage. The silicon dioxide layer will also decrease qualities and performances of the dielectric layer. The silicon dioxide layer will further decrease qualities of the semiconductor elements.

### SUMMARY OF THE INVENTION

In accordance with the background of the above-mentioned invention, the traditional method for using the hafnium dioxide layer to be the inter-layer dielectric layer and the gate dielectric layer will decrease the performances and the qualities of the dielectric layer and will decrease the qualities of the semiconductor elements. The present invention provides a method for using a silicate mixed layer to be the inter-layer dielectric layer or the gate dielectric layer to get the higher dielectric constant from the dielectric layer.

The second objective of the present invention is to increase the stability of the threshold voltage of the dielectric layer by using a silicate mixed layer to be the inter-layer dielectric layer or the gate dielectric layer.

The third objective of the present invention is to get a better conduction current density from the dielectric layer by using a silicate mixed layer to be the inter-layer dielectric layer or the gate dielectric layer.

The fourth objective of the present invention is to get a low interface state density from the dielectric layer by using a silicate mixed layer to be the inter-layer dielectric layer or the gate dielectric layer.

The fifth objective of the present invention is to get a low fixed charge density from the dielectric layer by using a silicate mixed layer to be the inter-layer dielectric layer or the gate dielectric layer.

The sixth objective of the present invention is to increase qualities of the inter-layer dielectric layer and the gate dielectric layer by using a silicate mixed layer to be the inter-layer dielectric layer or the gate dielectric layer.

The further objective of the present invention is to increase qualities of the semiconductor elements by using a silicate mixed layer to be the inter-layer dielectric layer or the gate dielectric layer.

In according to the foregoing objectives, the present invention provides a method for using a silicate mixed layer to be the inter-layer dielectric layer or the gate dielectric layer to form high qualities of the gate dielectric layer and the inter-layer dielectric layer. The first step of the present invention is to form a silicate layer on the substrate of the wafer by using a physical vapor deposition procedure. The silicate layer is a hafnium silicate layer or a zirconium silicate layer. Then the silicate layer is treated to become a gate dielectric layer or an inter-layer dielectric layer which has a higher dielectric constant by using a rapid thermal annealing procedure in a environment which is filled of nitrogen or ammonia. Using the method of the present invention will get the higher dielectric constant from the gate dielectric layer or the inter-layer dielectric layer and will increase the stability of the threshold voltage of the gate dielectric layer or the inter-layer dielectric layer. The method of the present invention will also get the better conduction current density, the low interface state density, and the low fixed charge density from the dielectric layer. The method of the present invention will further increase the qualities of the inter-layer dielectric layer and the gate dielectric layer and will further increase the qualities of the semiconductor elements.

### BRIEF DESCRIPTION OF THE DRAWINGS

In the accompanying drawing forming a material part of this description, there is shown:

FIG. 1 shows a diagram in forming a hafnium dioxide layer on a substrate of a wafer;

FIG. 2 shows a diagram in forming a conductive layer on the hafnium dioxide layer;

FIG. 3 shows a diagram in forming a silicon dioxide layer on an interface between the substrate and the hafnium dioxide layer;

FIG. 4 shows a diagram in forming plural field oxide regions in the substrate;

FIG. 5 shows a diagram in forming a silicate layer on the substrate and the plural field oxide regions;

FIG. 6 shows a diagram in forming a conductive layer on a silicate mixed layer; and

FIG. 7 shows a diagram in removing the partial conductive layer and the partial silicate mixed layer to show the partial silicon nitride layer.

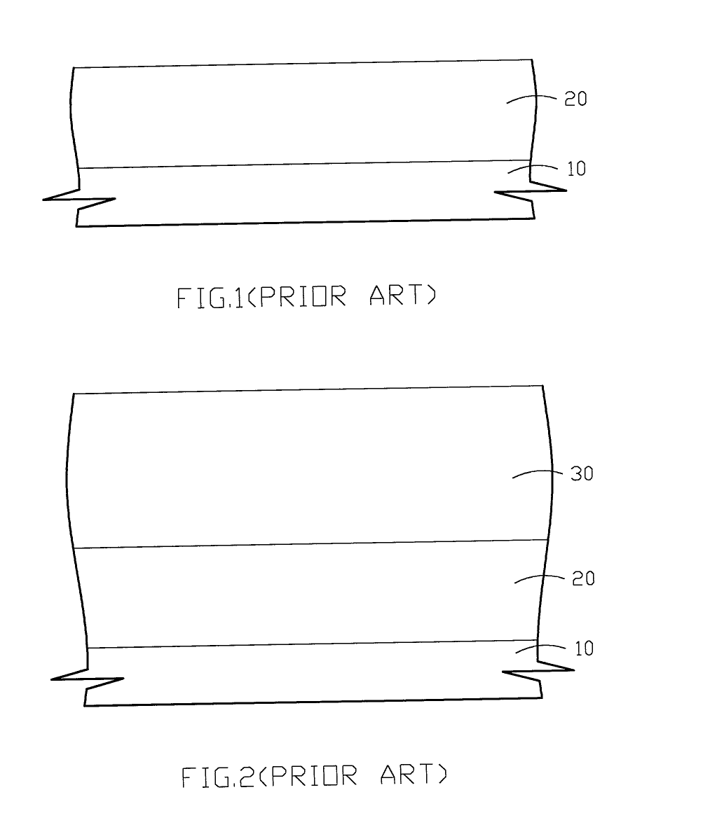

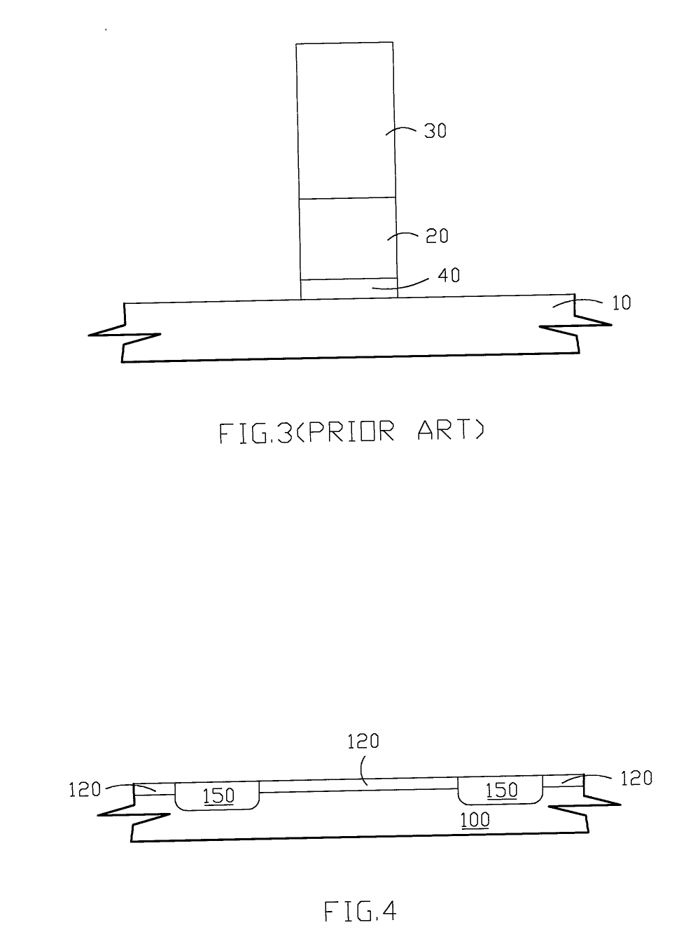

### DESCRIPTION OF THE PREFERRED EMBODIMENT

The foregoing aspects and many of the intended advantages of this invention will become more readily appreciated as the same becomes better understood by reference to the following detailed description, when taken in conjunction with the accompanying drawings, wherein:

Referring to FIG. 4, this shows a diagram in forming plural field oxide regions in the substrate. At first, a wafer, which comprises a substrate 100, is provided. This substrate 100 can be a silicon substrate. Then locations of active regions are defined and a field oxidation procedure is proceeded to form plural field oxide regions 150 in the substrate 100. Then hydrofluoric acid, whose concentration is 100:1, is used to clean the substrate 100 and to remove oxide, which is in the active regions of the substrate 100. If the oxide is remained in the active regions of the substrate 100, the oxide will affect qualities and performance of the semiconductor elements. Then the wafer is placed into a reaction chamber, which is filled of ammonia and nitrogen, to proceed the first rapid thermal annealing procedure to treat the substrate 100 and to form a silicon nitride layer 120 on the substrate 100. A thickness of the silicon nitride layer is about 3 to 5 angstroms. A proceeding temperature of the first rapid thermal annealing procedure is about 700 to 800° C. The best proceeding temperature of the first rapid thermal annealing procedure is about 750° C. The proceeding time of the first rapid thermal annealing procedure is about 30 seconds. The proceeding pressure of the first rapid thermal annealing procedure is about 1 atmosphere.

Referring to FIG. 5, this shows a diagram in forming a silicate layer on the substrate and the plural field oxide regions. A silicate layer 200 is formed on the silicon nitride layer 120 and the plural field oxide regions 150 by using the physical vapor deposition procedure. A thickness of the silicate layer 200 is about 40 to 60 angstroms. The advantage of the physical vapor deposition procedure is that if the proceeding temperature of the procedure is higher and higher, the deposition rate is lower and lower. The physical vapor deposition procedure usually uses following methods, such as: (1) evaporation technology; (2) molecular beam epitaxy (MBE) technology; (3) sputtering technology. Following the different needs of the procedure, the different method is used to proceed the physical vapor deposition procedure. The present invention uses the magnetron sputtering method to form the silicate layer 200 on the substrate 100 and the plural field oxide regions 150 but not limit the scope of the present invention.

Then the wafer is placed into the reaction chamber, which is filled of nitrogen and ammonia, to proceed the second rapid thermal annealing procedure to treat the silicate layer 200. The silicate layer 200 will become a silicate mixed layer 250, which is used to be the gate dielectric layer or the inter-layer dielectric layer. If a hafnium silicate layer is used to be the silicate layer 200, the hafnium silicate layer will become a hafnium silicate mixed layer, which comprises hafnium dioxide, silicon dioxide, and silicon nitride, after proceeding the second rapid thermal annealing procedure. A chemical formula of the hafnium silicate mixed layer, which comprises hafnium dioxide, silicon dioxide, and silicon nitride, is (HfO₂)_{X}(SiO₂)_{Y}(SiN)_{1-X-Y}. A value of X and a value of Y are greater than zero. A number, which express that X adds Y, is greater than 1. A proceeding temperature of the second rapid thermal annealing procedure is about 600 to 700° C. A proceeding time of the second rapid thermal annealing procedure is about 30 to 50 seconds.

If a zirconium silicate layer is used to be the silicate layer 200, the zirconium silicate layer will become a zirconium silicate mixed layer, which comprises zirconium dioxide, silicon dioxide, and silicon nitride, after proceeding the second rapid thermal annealing procedure. A chemical formula of the zirconium silicate mixed layer, which comprises zirconium dioxide, silicon dioxide, and silicon nitride, is (ZrO₂)_{X}(SiO₂)_{Y}(SiN)_{1-X-Y}. A value of X and a value of Y are greater than zero. A number, which express that X adds Y, is greater than 1. A proceeding temperature of the second rapid thermal annealing procedure is about 600 to 700° C. A proceeding time of the second rapid thermal annealing procedure is about 30 to 50 seconds.

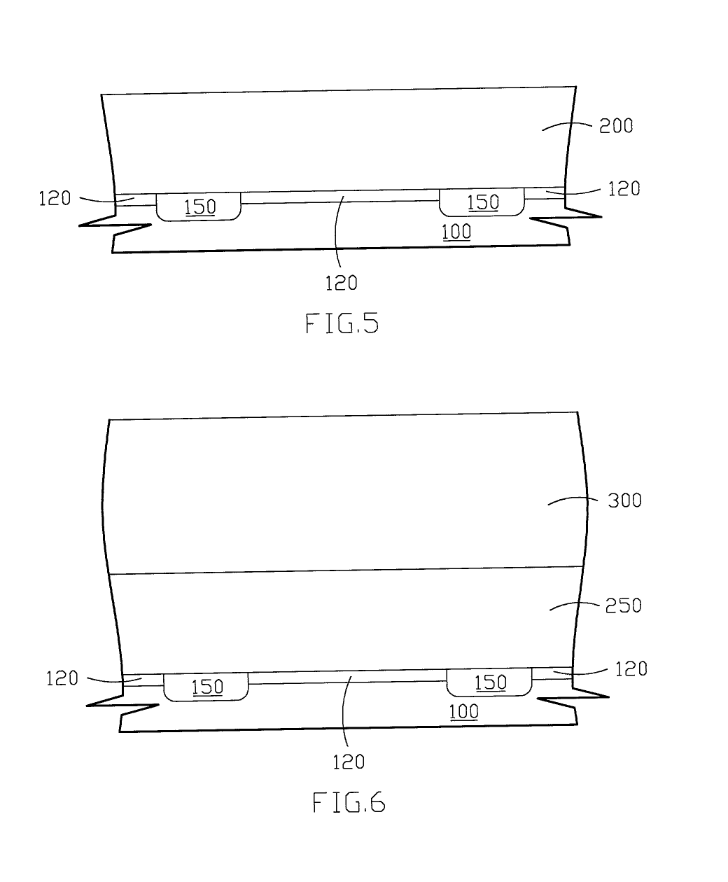

Referring to FIG. 6, this shows a diagram in forming a conductive layer on a silicate mixed layer. After the silicate mixed layer 250 is formed on the silicon nitride layer 120 and the plural field oxide regions 150 of the wafer, a conductive layer 300 is formed on the silicate mixed layer 250. A material of the conductive layer 300 is usually tantalum nitride, titanium nitride, or a silicon layer, wherein the silicon layer is polysilicon layer. When the material of the conductive layer 300 is tantalum nitride or titanium nitride, the conductive layer 300 is used to be the electrode and the silicate mixed layer 250 is used to be the inter-layer dielectric layer. When the material of the conductive layer 300 is the silicon layer, the conductive layer 300 is used to be the gate layer and the silicate mixed layer 200 is used to be the gate dielectric layer. Following different needs of the procedure, the different materials of the conductive layer 300 is used. In the present embodiment, tantalum nitride is used to be the material of the conductive layer 300 but the scope of the present invention is not limited. When tantalum nitride is used to be the material of the conductive layer 300, the tantalum nitride layer is formed on the silicate mixed layer 250 to be the electrode by using the sputtering procedure. The silicate mixed layer 250 is used to be the inter-layer dielectric layer.

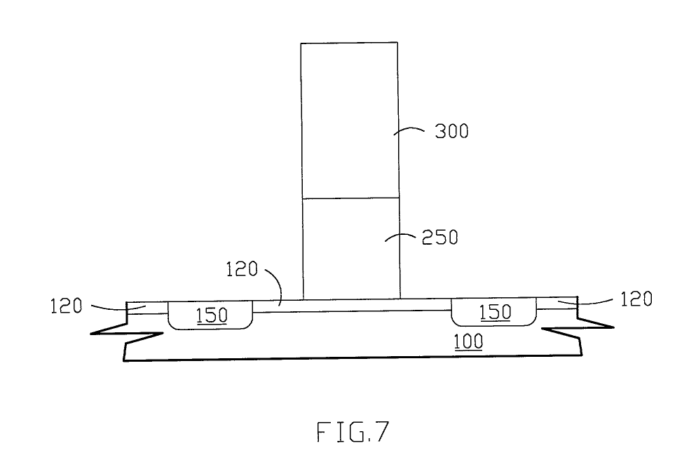

Referring to FIG. 7, this shows a diagram in removing the partial conductive layer and the partial silicate mixed to show the partial silicon nitride layer. The partial conductive layer 300 and the partial silicate mixed layer 250 are removed by using a photolithography and an etching procedure to show the partial silicon nitride layer 120. At last, ions, which are needed in the procedure, are implanted into the substrate and the third rapid thermal annealing procedure is proceeded to form a source/drain region in the substrate.

The silicon nitride layer 120, which is on the substrate 100, and the silicate mixed layer 250, which comprises silicon nitride, can be used to be diffusion block layers of the oxygen ions. When the wafer proceeds the third rapid thermal annealing procedure and following thermal oxide procedure, a silicon dioxide layer will not be formed on the interface between the substrate 100 and the silicate mixed layer 250 because of the diffusion block layers, which can prevent the oxygen ions to have the diffusion path to proceed the diffusion actions. Therefore, the interface charge trapping state and the threshold voltage variation will not occur on the interface between the substrate 100 and the silicate mixed layer 250. The silicate mixed layer 250 can also get the better conduction current density, the low interface state density, and the low fixed charge density from the dielectric layer.

If polysilicon is used to be a material of the conductive layer 300, the silicate mixed layer 250 is used to be the gate dielectric layer. The silicon nitride layer 120, which is on the substrate 100, and the silicate mixed layer 250, which comprises silicon nitride, can be used to be diffusion block layers of the oxygen ions. When the wafer proceeds the third rapid thermal annealing procedure and following thermal oxide procedure, the interface between the substrate 100 and the silicate mixed layer 250 will not occur the interface reactions because of the diffusion block layers, which can prevent the oxygen ions to have the diffusion path to proceed the diffusion actions. This condition will increase the dielectric constant of the gate dielectric layer and will make the gate dielectric layer have a stable threshold voltage. This kind of gate dielectric layer will also have the better conduction current density, the low interface state density, and the low fixed charge density

In accordance with the present invention, the present invention provides a method for using a silicate mixed layer to be the inter-layer dielectric layer or the gate dielectric layer to form high qualities of the gate dielectric layer and the inter-layer dielectric layer. The first step of the present invention is to form a silicate layer on the substrate of the wafer by using a physical vapor deposition procedure. The silicate layer is a hafnium silicate layer or a zirconium silicate layer. Then the silicate layer is treated to become a gate dielectric layer or an inter-layer dielectric layer which has a higher dielectric constant by using a rapid thermal annealing procedure in a environment which is filled of nitrogen or ammonia. Using the method of the present invention will get the higher dielectric constant from the gate dielectric layer or the inter-layer dielectric layer and will increase the stability of the threshold voltage of the gate dielectric layer or the inter-layer dielectric layer. The method of the present invention will also get the better conduction current density, the low interface state density, and the low fixed charge density from the dielectric layer. The method of the present invention will further increase the qualities of the inter-layer dielectric layer and the gate dielectric layer and will further increase the qualities of the semiconductor elements.

Although specific embodiments have been illustrated and described, it will be obvious to those skilled in the art that various modifications may be made without departing from what is intended to be limited solely by the appended claims.

What is claimed is:

1. A method for forming a silicate dielectric layer, said method comprises:
providing a wafer, wherein said wafer comprises a substrate;
forming a silicate layer on said substrate; and
proceeding a rapid thermal annealing procedure to make said silicate layer become a silicate mixed layer, wherein said silicate mixed layer is used to be said silicate dielectric layer.

2. The method according to claim 1, wherein said substrate comprises a silicon nitride layer.

3. The method according to claim 1, wherein said silicate layer is formed by using a magnetron sputtering procedure.

4. The method according to claim 1, wherein said silicate layer is a hafnium silicate layer.

5. The method according to claim 4, wherein said silicate mixed layer is a hafnium silicate mixed layer.

6. The method according to claim 5, wherein said hafnium silicate mixed layer comprises hafnium dioxide, silicon dioxide, and silicon nitride.

7. The method according to claim 5, wherein a chemical formula of said hafnium silicate mixed layer is (HfO₂)_{X}(SiO₂)_{Y}(SiN)_{1-X-Y}.

8. The method according to claim 7, wherein said X is greater than zero.

9. The method according to claim 7, wherein said Y is greater than zero.

10. The method according to claim 7, wherein a number, which expresses that said X adds said Y, is lower than 1.

11. The method according to claim 1, wherein said silicate layer is a zirconium silicate layer.

12. The method according to claim 11, wherein said silicate mixed layer is a zirconium silicate mixed layer.

13. The method according to claim 12, wherein said zirconium silicate mixed layer comprises zirconium dioxide, silicon dioxide, and silicon nitride.

14. The method according to claim 12, wherein a chemical formula of said zirconium silicate mixed layer is (ZrO₂)_{X}(SiO₂)_{Y}(SiN)_{1-X-Y}.

15. The method according to claim 14, wherein said X is greater than zero.

16. The method according to claim 14, wherein said Y is greater than zero.

17. The method according to claim 14, wherein a number, which expresses that said X adds said Y, is lower than 1.

18. The method according to claim 1, wherein a proceeding temperature of said rapid thermal annealing procedure is about 600 to 700° C.

19. The method according to claim 1, wherein a proceeding time of said rapid thermal annealing procedure is about 30 to 50 seconds.

20. The method according to claim 1, wherein said rapid thermal annealing procedure is proceeded in a environment, which is filled of a nitrogen.

21. The method according to claim 1, wherein said rapid thermal annealing procedure is proceeded in a environment, which is filled of a ammonia.

22. The method according to claim 1, wherein said substrate must be passed through a cleaning procedure.

23. The method according to claim 22, wherein a hydrofluoric acid is used in said cleaning procedure.

24. A method for forming a silicate dielectric layer, said method comprises:
providing a wafer, wherein said wafer comprises a substrate;
forming plural field oxide regions in said substrate;
cleaning said substrate by using a hydrofluoric acid;
proceeding a first rapid thermal annealing procedure to form a silicon nitride layer on said substrate, wherein said first rapid thermal annealing procedure is proceeded in a environment, which is filled of a gas;
forming a hafnium silicate layer on said substrate and said plural field oxide regions;
proceeding a second rapid thermal annealing procedure to make said hafnium silicate layer become a hafnium silicate mixed layer; and
forming a conductive layer on said hafnium silicate mixed layer.

25. The method according to claim 24, wherein said gas is ammonia.

26. The method according to claim 24, wherein said gas is nitrogen.

27. The method according to claim 24, wherein said hafnium silicate layer is formed by using a magnetron sputtering procedure.

28. The method according to claim 24, wherein said hafnium silicate mixed layer comprises hafnium dioxide, silicon dioxide, and silicon nitride.

29. The method according to claim 24, wherein a chemical formula of said hafnium silicate mixed layer is (HfO₂)_{X}(SiO₂)_{Y}(SiN)_{1-X-Y}.

30. The method according to claim 29, wherein said X is greater than zero.

31. The method according to claim 29, wherein said Y is greater than zero.

32. The method according to claim 29, wherein a number, which expresses that said X adds said Y, is lower than 1.

33. The method according to claim 24, wherein a proceeding temperature of said first rapid thermal annealing procedure is about 700 to 800° C.

34. The method according to claim 24, wherein a proceeding temperature of said second rapid thermal annealing procedure is about 600 to 700° C.

35. The method according to claim 24, wherein a proceeding time of said second rapid thermal annealing procedure is about 30 to 50 seconds.

36. The method according to claim 24, wherein said second rapid thermal annealing procedure is proceeded in a environment, which is filled of a nitrogen.

37. The method according to claim 24, wherein said second rapid thermal annealing procedure is proceeded in a environment, which is filled of a ammonia.

38. The method according to claim 24, wherein a material of said conductive layer is tantalum nitride.

39. The method according to claim 24, wherein a material of said conductive layer is titanium nitride.

40. The method according to claim 38, wherein said hafnium silicate mixed layer is used to be an inter-layer dielectric layer.

41. The method according to claim 24, wherein a material of said conductive layer is silicon layer.

42. The method according to claim 41, wherein said hafnium silicate mixed layer is used to be a gate dielectric layer.
